(19) United States
(12) Patent Application Publication
(10) Pub. No.: US 2026/0020175 A1
(43) Pub. Date: Jan. 15, 2026

(54) CABLE MANAGEMENT ASSEMBLY WITH SPRING-BIASED AUTO-LATCH

(71) Applicant: Aivres Systems Inc., San Jose, CA (US)

(72) Inventor: Jing Sheng JAN, New Taipei City (TW)

(21) Appl. No.: 19/335,819

(22) Filed: Sep. 22, 2025

(51) Int. Cl. H05K 5/02; H05K 5/03; H05K 7/20

(52) U.S. Cl. CPC H05K 5/0247; H05K 5/0221; H05K 5/0226; H05K 5/023; H05K 5/03; H05K 7/20145

(57) ABSTRACT

A cable management assembly for a mounting surface includes a surface-mount structure, a cable cover structure movable between a closed cable-retaining position and an open cable-access position, and a handle structure coupled to the cable cover structure through a releasable latch interface. A first spring biases the handle to a default latched position that prevents opening; moving the handle against the spring shifts the latch to an unlocking position permitting the cover to open, and closing the cover causes the spring to return the handle and re-latch without tools. In some embodiments a rotating-shaft structure with a hinge barrel and insertion pin provides the motion; guiding apertures and followers form the latch; spaced upper and lower brackets and an optional second spring provide assisted opening; and an optional brush fixed to the cover impedes airflow into the cover interior while allowing cable passage.

### TECHNICAL FIELD

The disclosure relates to cable management hardware for electronic equipment enclosures. More particularly, it concerns surface-mounted cable cover assemblies that secure one or more cables on a chassis or other mounting surface and that provide tool-free opening and spring-assisted automatic re-latching.

### BACKGROUND

Electronic systems such as servers, storage appliances, and network devices rely on organized cable routing to maintain serviceability and thermal performance. Conventional cable clips and covers are typically fixed to a chassis by screws and require hand tools for installation, removal, and rework. Tool-dependent fixtures slow factory assembly and field maintenance and can expose nearby printed circuit boards and components to accidental contact from tools during service. Many existing clips also provide only a single function (mechanically holding cables) while admitting airflow into non-functional cavities that reduces cooling efficiency. In addition, fixed-geometry mounts make it difficult to scale the same design across different cable bundle sizes or to accommodate varying clearances in different platforms. There is a need for a cable management assembly that retains cables securely yet opens without tools, re-latches automatically when closed, reduces assembly and service time, and can be adapted across systems with different cable capacities. It is also desirable that such an assembly cooperate with chassis airflow by limiting leakage into the cable cover interior.

### SUMMARY

A cable management assembly can be configured to perform particular operations or actions by virtue of its mechanical structures (including hardware components and their arrangements) that, in operation, cause the assembly to perform the actions. One or more embodiments can be configured to perform particular operations or actions by virtue of the structural features described herein, which, when assembled and used as disclosed, cause the apparatus to perform the actions.

In the figures and the following description, the components of the cable management assembly are labeled consistently as described below.

### Cable Cover Structure 100

Panel body 102 of the cable cover structure 100 (e.g., a rectangular panel body with reinforcement ribs/grid on its exterior face)
Hinge barrel 103 of the cable cover structure 100 (e.g., cylindrical hinge element along the top edge of the panel body 102, aligned with the rotating shaft structure 110 for pivoting)
Top plate 106 of the cable cover structure 100 (e.g., overlaps with the upper surface-mount bracket 140).
Bottom plate 107 of the cable cover structure 100 (e.g., overlaps with the lower surface-mount bracket 150).
Protrusion structure 108 on the top plate 106 of the cable cover structure 100 (spring stop) (edge/corner feature that serves as an abutment for a first spring 135).
Rotating shaft structure 110 (e.g., bar with cylindrical sleeves fixed to the chassis surface, forming the stationary hinge).
Insertion pin 120 (e.g., elongated pin inserted through aligned hinge sleeves/cylindrical sleeves of the Rotating shaft structure and hinge barrel, defining pivot axis).

### Handle and Latch Mechanism

Handle structure 130 (e.g., elongated sliding bar disposed above the cable cover structure).
Guiding slot 131 in the handle structure 130 (e.g., elongated hole on the handle structure 130, allowing the handle structure 130 to move along the guiding slot 131).
Arrow marking 132 on the handle structure 130 (e.g., provides visual instruction for operator push direction).
Screw(s) 133 through handle structure (e.g., pass through guiding slots 131 into the cable cover structure 100 on a corresponding nut 138, constraining sliding motion).
Nut 138 (e.g., a captive nut/rivet-nut fixed to the cable cover structure 100 that receives screw 133 passing through guiding slot 131).
Clearance gap 134 under screw head (e.g., ensures handle structure 130 can slide smoothly without binding).
First spring 135 (e.g., coil spring between handle structure 130 and protrusion structure 108, which biases handle structure 130 away from protrusion structure 108 in default state/default latched position, resets latch on closure).
Mounting holes 136 on top plate 106 of the cable cover structure 100 (e.g., for mating with screws/rivets 146 on the upper surface-mount bracket 140, the screws/rivets 146 engage with the guiding opening(s) 137 on the handle structure 130).
Guiding opening(s) 137 on the handle structure 130 (e.g., stepped or keyhole-type apertures having a narrow retaining portion that captures a follower to inhibit lift and a larger release portion that allows the follower to disengage for opening; the “follower” may be screws/rivets 146 carried by the upper surface-mount bracket 140).

### Surface-Mount Structure

Upper surface-mount bracket 140 (e.g., a T-shaped structure, base fixed to chassis, perpendicular tab projects outward; overlaps with top plate 106 of cable cover).
Lower surface-mount bracket 150 (e.g., a T-shaped structure, base fixed to chassis, perpendicular tab projects outward; overlaps with bottom plate of cable cover).
Mounting holes 142 in the upper and lower brackets (e.g., for screws or rivets to secure to chassis).
Stopper protrusion 143 on the surface-mount bracket 150 (e.g., rivet head, screw head, or bump limiting inward travel of cable cover).
Spring post 144 on the lower surface-mount bracket 150 (e.g., pin or peg that seats the second spring 145 on the lower surface-mount bracket 150, provides upward/popping force to assist initial opening of cable cover).
Screws/rivets 146 on the upper surface-mount bracket 140

### Airflow Management

Brush structure 150 (e.g., L-shaped unit fixed to one end of cable cover structure).
Brush mounting plate 152 (e.g., leg of L with holes for screws or rivets).
Bristles of brush 154 (e.g., flexible fibers forming airflow barrier while allowing cables to pass through).

In one general aspect, the cable management assembly may include a surface-mount structure configured for attachment to the mounting surface. The cable management assembly may also include a cable cover structure 100 movably coupled to the surface-mount structure between a closed position, in which the cable cover structure retains the at least one cable, and an open position, in which the cable cover structure provides access for placement or removal of the at least one cable. The assembly may furthermore include a handle structure 130 mounted on the cable cover structure 100 for guided motion between a default latched position and an unlocking position, the handle structure cooperating with the cable cover structure 100 and the surface-mount structure to define a releasable latch interface. The assembly may in addition include a first spring 135 operatively coupled between the handle structure 130 and the cable cover structure 100 and biasing the handle structure 130 toward the default latched position. The releasable latch interface may be configured such that, when the handle structure 130 is in the default latched position, the cable cover structure 100 is prevented from moving from the closed position to the open position; movement of the handle structure 130 against a bias of the first spring 135 to the unlocking position permits the cable cover structure 100 to move from the closed position toward the open position; and returning the cable cover structure 100 toward the closed position causes the first spring 135 to drive the handle structure 130 toward the default latched position to re-engage the releasable latch interface and secure the at least one cable. Other embodiments of this aspect may include corresponding apparatus and methods, each configured to perform the actions of the methods.

In some embodiments, the cable cover structure 100 may be pivotally coupled to the surface-mount structure by a rotating shaft structure 110, a hinge barrel 103 on the cable cover structure 100, and an insertion pin 120 extending through the rotating shaft structure 110 and the hinge barrel 103 to define a pivot axis. The rotating shaft structure 110 may be fixed to the surface-mount structure by rivets 160, and the insertion pin 120 may include an axial retention feature configured to prevent lateral migration under vibration.

The handle structure 130 may be constrained for guided motion by at least one guiding slot 131 and a fastener that passes through the guiding slot 131 while maintaining a clearance gap 134 that permits sliding of the handle structure 130 without binding. The fastener may include a screw 133, and the clearance gap 134 may be set by at least one of a screw head geometry, a washer, or a shoulder portion of the screw 133. An end of the guiding slot 131 proximate the protrusion structure 108 may define a stop for the default latched position, and an opposite end of the guiding slot 131 may define a stop for the unlocking position, thereby defining a tool-free latch operation. The fastener that passes through the guiding slot 131 may be threaded into a captive nut or rivet-nut fixed to the cable cover structure 100 to provide repeatable serviceability.

The releasable latch interface may include at least one aperture portion (guiding opening 137) of the handle structure 130 and at least one follower on the upper surface-mount bracket 140 or the cable cover structure 100, the aperture portion including a retaining portion that inhibits opening in the default latched position and a release portion that permits opening in the unlocking position. The aperture portion (guiding opening 137) may be keyhole-shaped, and the follower may include one of the screws/rivets 146, a boss, or a screw head on the upper surface-mount bracket 140 or the cable cover structure 100. In some embodiments, the follower may include the screws/rivets 146 on the upper surface-mount bracket 140 or the cable cover structure 100, and the retaining region of the aperture portion may be dimensioned to capture the follower with minimal play in the default latched position.

The first spring 135 may be positioned between an end portion of the handle structure 130 and a protrusion structure 108 on the cable cover structure 100 that serves as a spring stop, the first spring 135 biasing the handle structure 130 away from the protrusion structure 108 in the default latched position. The assembly may include a second spring configured to apply an opening bias to the cable cover structure 100 when the handle structure 130 is in the unlocking position. The second spring may include at least one of a coil spring seated on a spring post of the surface-mount structure, a torsion spring adjacent the pivot axis, a leaf spring, or an elastomeric biasing element, and the second spring may provide an initial pop-up force that begins separation of the cable cover structure 100 from the lower surface-mount bracket when the handle structure 130 reaches the unlocking position.

The surface-mount structure may include an upper surface-mount bracket 140 and a lower surface-mount bracket spaced from the upper surface-mount bracket to receive the cable cover structure 100 therebetween. Each of the upper surface-mount bracket 140 and the lower surface-mount bracket may have a T-shaped geometry including a flat base configured for attachment to the mounting surface and a perpendicular tab that projects outward to support the cable cover structure 100. The assembly may include a stopper protrusion 143 on at least one perpendicular tab of the surface-mount structure, the stopper protrusion 143 limiting inward travel of the cable cover structure 100 in the closed position. A spacing between the upper surface-mount bracket 140 and the lower surface-mount bracket may be selectable to accommodate cable cover structures of different heights or cable capacities, and a top plate 106 of the cable cover structure 100 may overlap the upper surface-mount bracket 140 while a bottom plate 107 of the cable cover structure 100 may overlap the lower surface-mount bracket in the closed position.

The assembly may include a brush structure fixed to an end of the cable cover structure 100 and arranged to impede airflow into an interior of the cable cover structure 100 while permitting passage of at least one cable. The brush structure may include an L-shaped brush mounting plate 152 secured to the cable cover structure 100 and a bristle portion forming a flexible barrier that deflects cooling airflow away from an interior of the cable cover structure 100.

The handle structure 130 may include an arrow marking 132 indicating a sliding direction toward the protrusion structure 108 to transition to the unlocking position and a rotation direction toward the mounting surface to open the cable cover structure 100. The panel body 102 may include reinforcement ribs that stabilize the cable cover structure 100. Implementations of the described techniques may include hardware embodiments and associated methods or processes.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 illustrates a conventional screw-fastened cable clip for chassis mounting (prior art).

FIG. 2 illustrates an example cable cover structure 100, in accordance with some embodiments.

FIG. 3 illustrates an assembly of a handle structure 130, guided fastening, and first spring 135 on the cable cover structure 100, in accordance with some embodiments.

FIG. 4 illustrates a zoom-in view of the guided fastening between the handle structure 130 and the cable cover structure 100, in accordance with some embodiments.

FIG. 5 illustrates an L-shaped brush structure 150 fixed at one end of the cable cover structure 100 to impede airflow while allowing cable passage, in accordance with some embodiments.

FIG. 6A illustrates an upper surface-mount bracket 140 with T-shaped geometry and outward tab for supporting the cable cover structure 100, in accordance with some embodiments.

FIG. 6B illustrates a lower surface-mount bracket 150 with T-shaped geometry and outward tab for supporting the cable cover structure 100, in accordance with some embodiments.

FIG. 7 illustrates an example installation of the upper and lower surface-mount brackets on a chassis sidewall to receive the cable cover structure 100, in accordance with some embodiments.

FIG. 8 illustrates an indication arrow on the handle structure 130 indicating two operation positions, in accordance with some embodiments.

FIG. 9A illustrates operation to move the handle structure 130 from a default latched/closed position to the first position, i.e., an unlocking position, by sliding the handle structure 130 toward the protrusion structure 108 to compress the first spring 135, in accordance with some embodiments.

FIG. 9A illustrates operation to move the handle structure 130 from the first position, i.e., an unlocking position, to the second position, i.e., an open position, by turning the handle structure 130 toward the mounting surface, in accordance with some embodiments.

FIG. 10 illustrates a secondary spring element integrated with the lower surface-mount bracket providing an initial pop-up force to assist opening, in accordance with some embodiments.

FIG. 11 illustrates placement of one or more cables within the interior of the cable cover structure 100 in the open position, in accordance with some embodiments.

FIG. 12 illustrates closure of the cable cover structure 100 and automatic return of the handle structure 130 to the default latched position under the bias of the first spring 135, in accordance with some embodiments

FIG. 13 illustrates the cable cover structure 100 with brush structure 150 blocking fan airflow from entering the interior of the cable cover and redirecting the airflow toward regions requiring cooling, in accordance with some embodiments.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

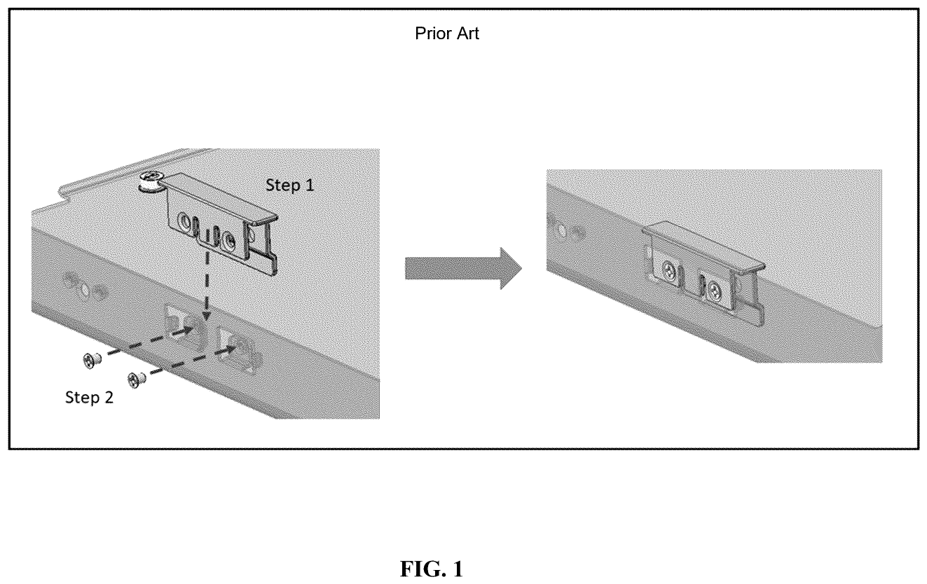

FIG. 1 illustrates a conventional screw-fastened cable clip for chassis mounting (prior art). As shown, the conventional design requires a two-step installation process. In a first step, the clip body is positioned against a chassis surface at a designated mounting location. In a second step, multiple screws are inserted through openings in the clip body and threaded into corresponding mounting holes of the chassis surface to secure the clip body in place. Once installed, the clip body defines an enclosure through which one or more cables may be routed. In this prior-art approach, both installation and removal require the use of hand tools, such as a screwdriver, to engage or disengage the screws. This tool-dependent process increases assembly and servicing time and introduces a risk of accidental contact between the screwdriver and nearby components, such as electronic components mounted on an adjacent printed circuit board. Furthermore, the conventional clip performs only a simple cable-retaining function and does not provide features such as tool-free operation, spring-assisted latching, or airflow management.

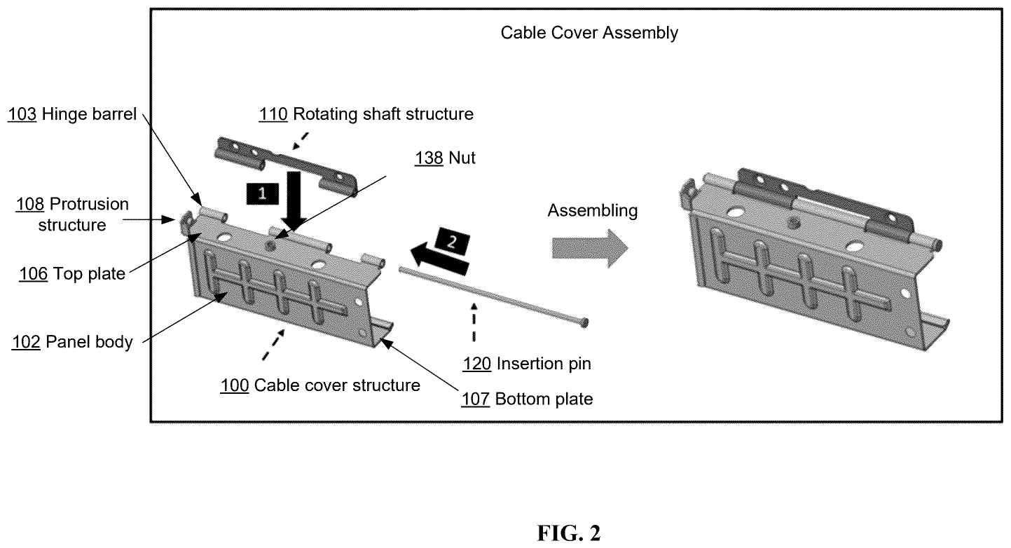

FIG. 2 illustrates an example cable cover structure 100 and its assembly with a rotating shaft structure 110 and an insertion pin 120, in accordance with some embodiments.

In some embodiments, the cable cover structure 100 includes a panel body 102 that is substantially rectangular and configured to enclose one or more cables against a chassis surface. The exterior face of the panel body 102 may incorporate a series of reinforcement ribs or a lattice grid to increase rigidity and resist bending when cables are pressed against the structure.

Along a top edge of the panel body 102, the cable cover structure 100 may include a hinge barrel 103. In some embodiments, the hinge barrel 103 is a cylindrical element dimensioned to mate coaxially with hinge sleeves of the rotating shaft structure 110. A protrusion structure 108 is formed at a corner or an end-side of the top plate 106 of the cable cover structure 100 and serves as a spring stop for a first spring 135 (described in later figures). The top plate 106 is configured to overlap with an upper surface-mount bracket 140 (described later), while the bottom plate 107 is configured to overlap with a lower surface-mount bracket 150 (described later). A nut 138 (e.g., a captive nut/rivet-nut) is disposed on the top plate 106, configured to receive screw 133 passing through guiding slot 131 (described later).

The rotating shaft structure 110 is a bar-like member with cylindrical sleeves intended to be fixed to a chassis surface or a mounting bracket. The rotating shaft structure 110 forms the stationary hinge element of the assembly.

The insertion pin 120 is an elongated rod configured to pass through the coaxially aligned hinge barrel 103 of the cable cover structure 100 and the sleeves of the rotating shaft structure 110. When fully inserted, the insertion pin 120 defines a pivot axis and prevents lateral separation between the cable cover structure 100 and the rotating shaft structure 110, while still allowing free rotational movement.

In one example, the assembly process proceeds in two steps. In Step 1, the hinge barrel 103 of the cable cover structure 100 is aligned with the cylindrical sleeves of the rotating shaft structure 110. In Step 2, the insertion pin 120 is axially advanced through both the hinge barrel 103 and the sleeves of the rotating shaft structure 110, thereby locking the two components together into a continuous hinge joint.

When the rotating shaft structure 110 is fixed to the mounting bracket or a surface of chassis, it allows the cable cover structure 100 to swing open relative to the rotating shaft structure 110 for cable insertion or removal, and to return securely to the closed position to retain cables.

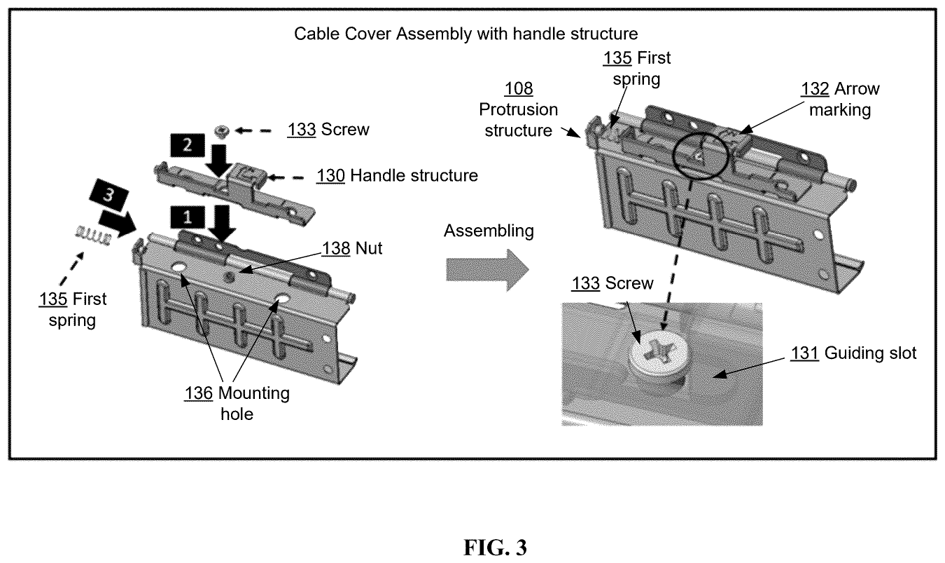

FIG. 3 illustrates an assembly of a handle structure 130, guided fastening (with a guiding slot 131), and first spring 135 on the cable cover structure 100, in accordance with some embodiments.

In the illustrated embodiment, the handle structure 130 is a substantially elongated bar positioned above the cable cover structure 100 and formed with at least one guiding slot 131 extending longitudinally. During assembly, the handle structure 130 is placed over the top plate 106 (Step 1), a screw 133 is inserted through the guiding slot 131 (Step 2) and threaded into a nut 138 positioned to receive the screw 133, thereby coupling the handle structure 130 to the cable cover structure 100 while constraining the handle structure 130 to guided, in-plane motion along the axis of the guiding slot 131. A clearance gap 134 is preferably maintained beneath the head of the screw 133 to permit smooth sliding of the handle structure 130 without binding.

The first spring 135 is positioned between an end of the handle structure 130 and a protrusion structure 108 on the top plate 106 (Step 3), the protrusion structure 108 functioning as a spring stop against which the first spring 135 is compressed when the handle structure 130 is actuated.

An arrow marking 132 on the handle structure 130 indicates the intended operator push direction for sliding the handle structure 130 along the guiding slot 131.

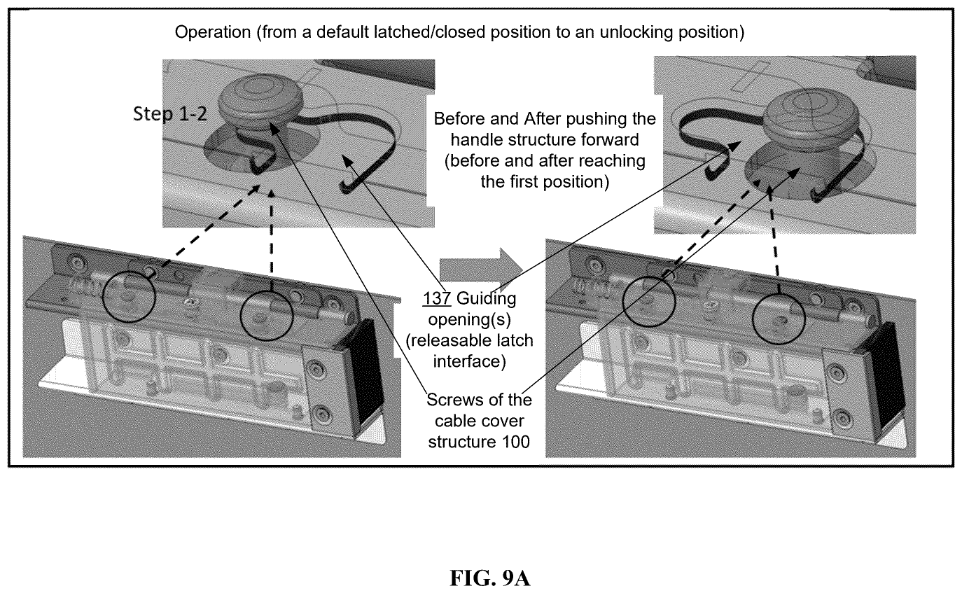

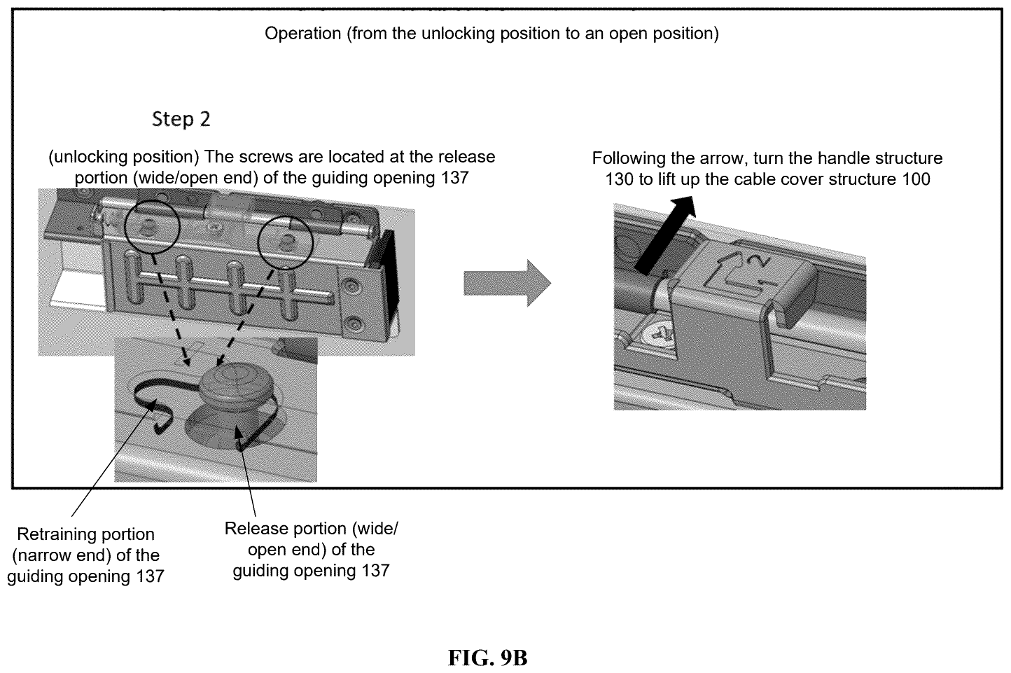

The mounting holes 136 on the top plate 106 are provided to mate with screws/rivets 146 of an upper surface-mount bracket 140. Those screws/rivets 146 engage guiding opening(s) 137 (not shown in FIG. 3 but shown in FIGS. 9A and 9B) formed in the handle structure 130 to implement the releasable latch interface.

In operation, the first spring 135 biases the handle structure 130 away from the protrusion structure 108 so that the screw 133 rests at the end of the guiding slot 131 nearest the protrusion structure 108 in a default state (also called a default latched or closed state), and when an operator slides the handle structure 130 toward the protrusion structure 108, the first spring 135 is compressed and the screw 133 travels to the opposite end of the guiding slot 131 to define the maximum stroke. Upon release, the first spring 135 returns the handle structure 130 toward the default state, thereby preparing the latch to re-engage when the cable cover structure 100 is closed.

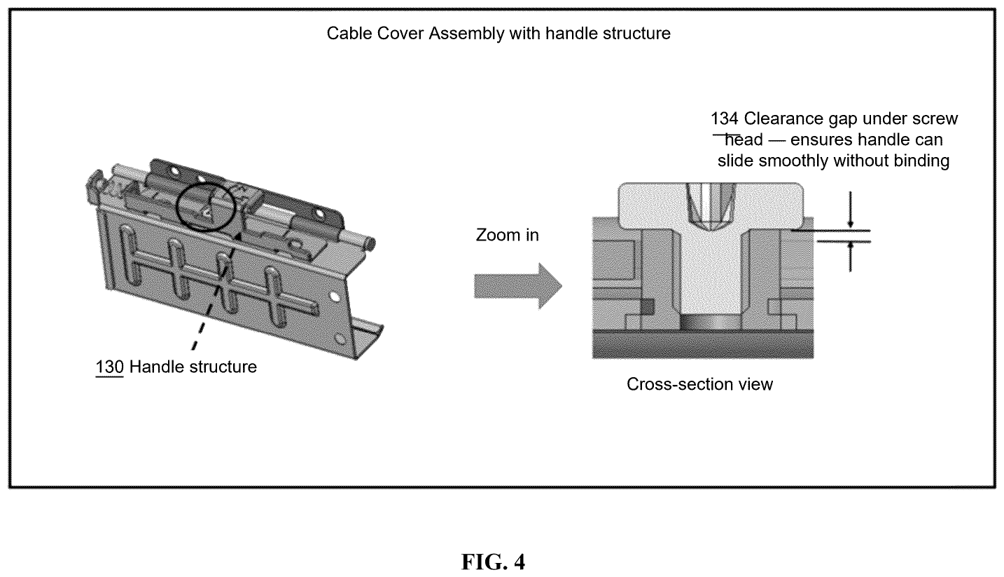

FIG. 4 illustrates a zoom-in view of the guided fastening between the handle structure 130 and the cable cover structure 100, in accordance with some embodiments. The perspective view at left identifies the fastening location on the handle structure 130. The cross-section view at right shows a screw 133 passing through a guiding slot 131 of the handle structure 130 and threading into a nut 138 associated with the cable cover structure 100 (for example, on or beneath the top plate 106). A deliberate clearance gap 134 is maintained between the underside of the screw head and the upper surface of the handle structure 130. The screw shank locates within the guiding slot 131 to constrain the handle structure 130 to in-plane, linear motion along the slot, while the clearance gap 134 prevents the screw head from clamping the handle structure 130, thereby allowing smooth sliding without binding. The head of the screw 133 is larger than the width of the guiding slot 131 so that the handle structure 130 is retained against upward lift, and the ends of the guiding slot 131 define the travel limits for the handle structure 130 during operation. The clearance gap 134 may be established by the screw head geometry, a washer, or a shoulder portion of the screw 133

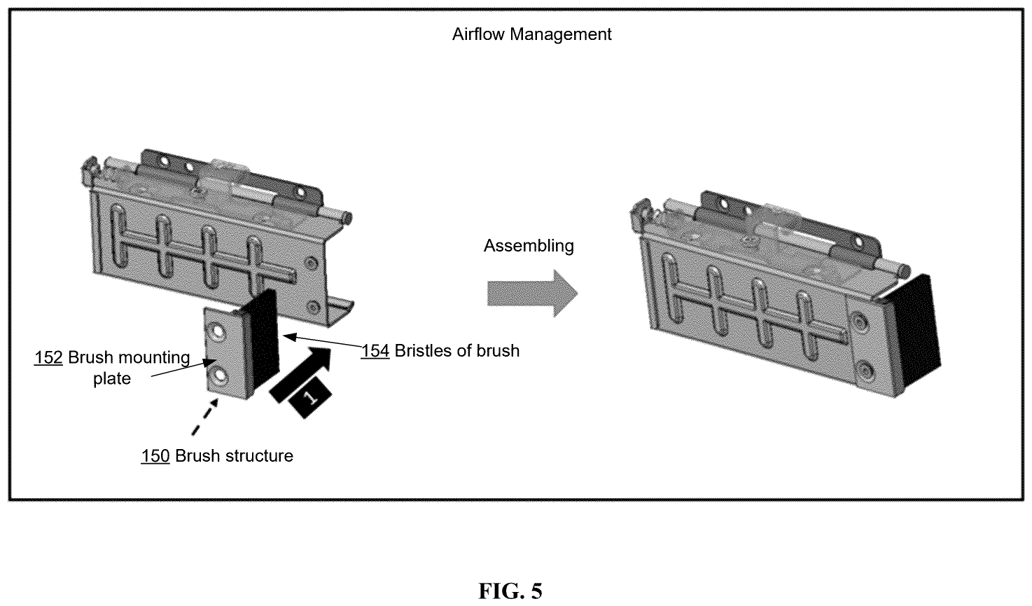

FIG. 5 illustrates an L-shaped brush structure 150 fixed at one end of the cable cover structure 100 to impede airflow while allowing cable passage, in accordance with some embodiments. As shown in the illustrated embodiment, the brush structure 150 includes a brush mounting plate 152 and a bristle portion 154 arranged at approximately a right angle to form an L-profile. The brush mounting plate 152 is positioned against the end face of the cable cover structure 100 (e.g., adjacent the panel body 102 and the top plate 106) and is secured to the cable cover structure 100 by suitable fasteners (e.g., screws or rivets), so that the brush structure 150 moves in unison with the cable cover structure 100 when the cover is opened and closed. The bristles 154 extend outward from the brush mounting plate 152 to define a flexible barrier. When the cable cover structure 100 is in the closed position, the bristles 154 occupy the cable pass-through opening at the end of the cover and conform around one or more cables to substantially block bulk airflow into the interior of the cable cover structure 100 while still permitting the cables to pass through with minimal resistance. In assembly, the brush structure 150 is brought toward the end of the cable cover structure 100 and fastened via the brush mounting plate 152, as indicated.

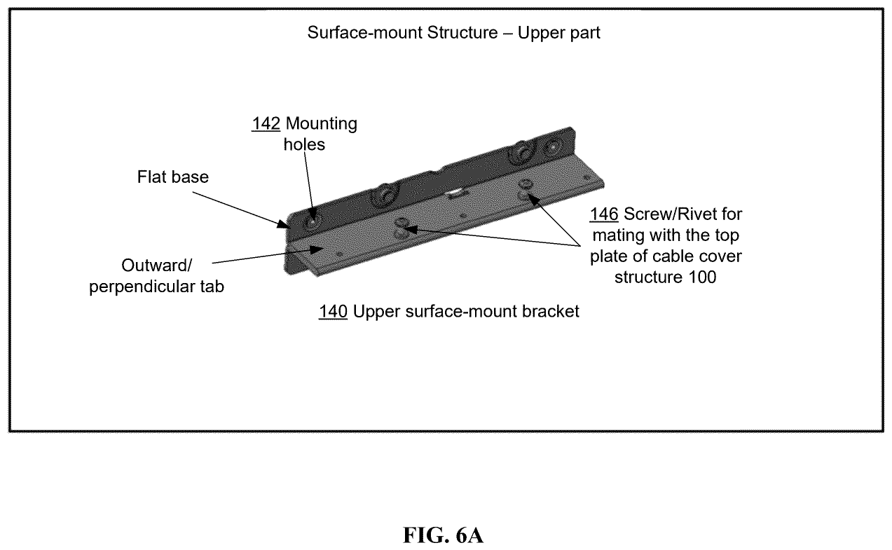

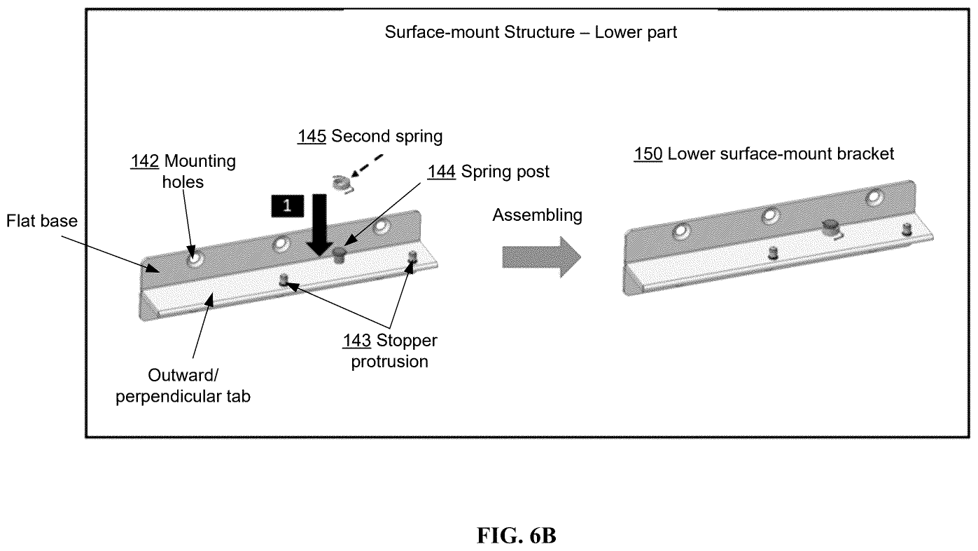

FIG. 6A illustrates an upper surface-mount bracket 140 with T-shaped geometry and outward tab for supporting the cable cover structure 100, in accordance with some embodiments. As shown, a flat base of the upper surface-mount bracket 140 lies flush against a chassis sidewall and includes mounting holes 142 to receive fasteners that attach the bracket to the mounting surface. A perpendicular (outward) tab projects outward from the base to support and interface with the cable cover structure 100. In the example shown, one or more screws/rivets 146 are provided on the outward tab (or a forward face) of the upper surface-mount bracket 140. During integration with the cable cover structure 100, the screws/rivets 146 are positioned to mate with mounting holes 136 in the top plate 106 and to pass through or cooperate with guiding opening(s) 137 of the handle structure 130, thereby acting as followers for the releasable latch interface described with reference to FIGS. 9A and 9B.

FIG. 6B illustrates a lower surface-mount bracket 150 with T-shaped geometry and outward tab for supporting the cable cover structure 100, in accordance with some embodiments. The lower surface-mount bracket 150 includes a flat base with mounting holes 142 for attachment to the chassis sidewall and a perpendicular tab projecting outward to receive the bottom plate 107 of the cable cover structure 100. The lower surface-mount bracket 150 further includes a spring post 144 on which a second spring 145 (shown as a coil spring) is seated. When the cable cover structure 100 is unlocked, the second spring 145 provides an initial pop-up or opening bias that assists lifting of the cover. One or more stopper protrusions 143 on the outward tab limit inward travel of the cable cover structure 100 when closed, ensuring repeatable seating and preventing the cable cover structure from being pushed too far toward the chassis.

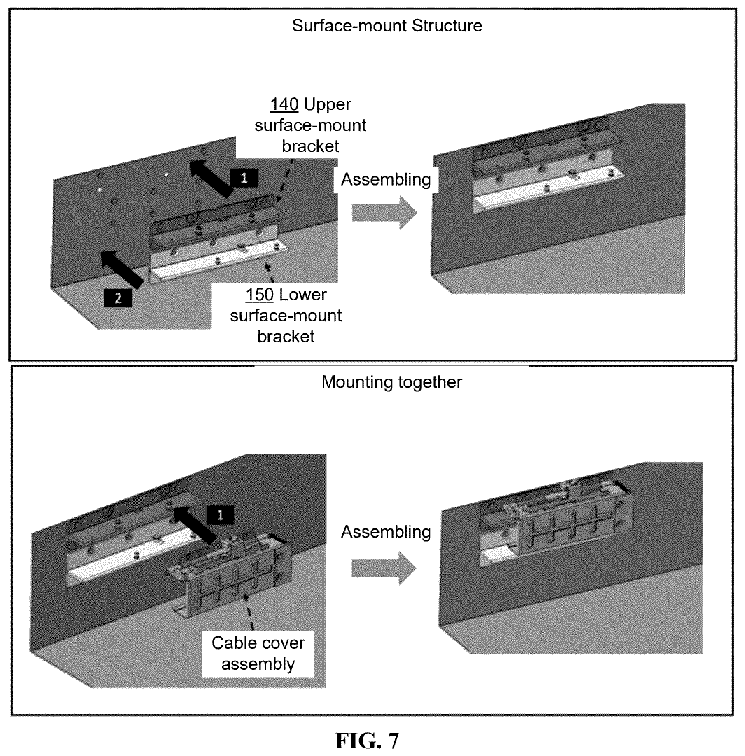

FIG. 7 illustrates an example installation of the upper and lower surface-mount brackets on a chassis sidewall to receive the cable cover structure 100, in accordance with some embodiments. As shown in the top part of FIG. 7, the upper surface-mount bracket 140 and the lower surface-mount bracket 150 are fixed to the sidewall with a selected vertical spacing so that the top plate 106 and bottom plate 107 of the cable cover structure 100 will overlap the respective brackets when the assembly is closed. The chosen spacing can be varied to accommodate different sizes of the cable cover structure 100 and different cable bundle capacities. With the brackets installed, their outward tabs define a receiving channel for the cable cover structure 100; the screws/rivets 146 on the upper surface-mount bracket 140 are thereby aligned to mate with the mounting holes 136 and to cooperate with the guiding opening(s) 137 of the handle structure 130, and the spring post 144 with the second spring 145 on the lower surface-mount bracket 150 is positioned to provide the opening assist when the cover is unlocked.

In the lower part of FIG. 7, the cable cover assembly (from FIGS. 2 and 3, which include the cable cover structure 100 pivotally coupled to a rotating shaft structure 110 by an insertion pin 120, and the handle structure 130 mounted as described above) is advanced toward the installed brackets (Step 1) and seated into the receiving channel defined by the outward tabs of the brackets. When seated, fasteners such as screws/rivets 146 on the upper surface-mount bracket 140 are aligned to mate with mounting holes 136 of the top plate 106 and to cooperate with guiding opening(s) 137 of the handle structure 130 as part of the releasable latch interface (see FIGS. 9A and 9B). The lower surface-mount bracket 150 may include stopper protrusions 143 that limit inward travel of the cable cover structure 100 to ensure repeatable seating, and a spring post 144 carrying a second spring 145 positioned to provide an initial pop-up bias when the cover is unlocked. After installation, the assembly allows the cable cover structure 100 to pivot open for cable access and to close for retention while interacting with the brackets, latch interface, and springs as described herein.

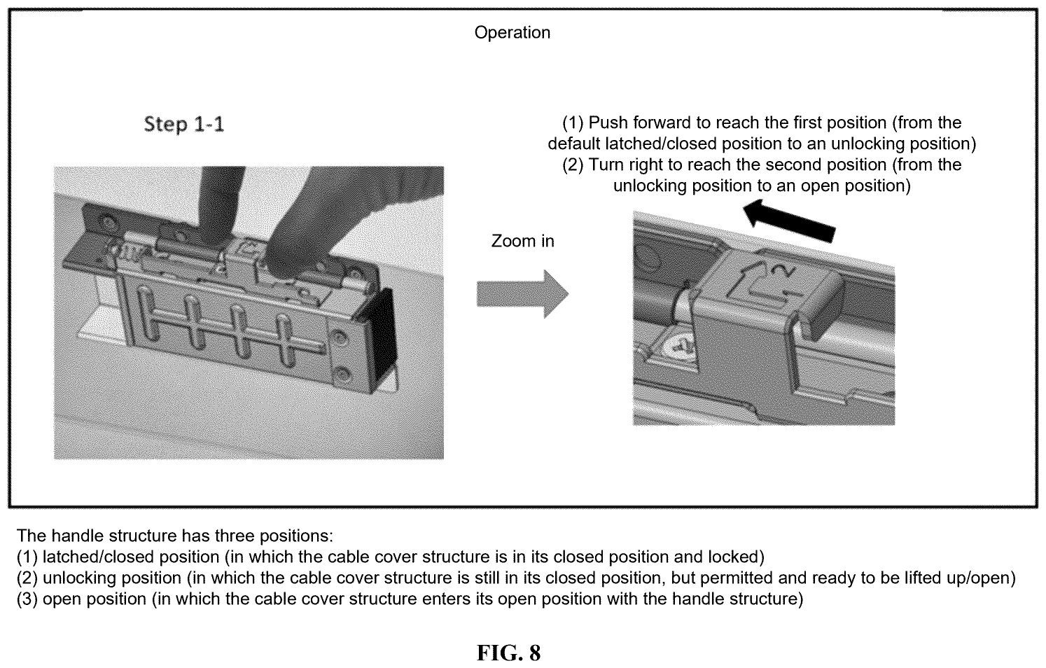

FIG. 8 illustrates an indication arrow on the handle structure 130 indicating two operation positions, in accordance with some embodiments. In the illustrated embodiment, the arrow marking 132 includes a straight arrow and a curved arrow. In the first stage indicated by the straight arrow, the operator may push the handle structure 130 forward along its guiding slot 131. This guided translation is defined by a screw 133 that passes through the guiding slot 131 and engages a nut 138 associated with the cable cover structure 100, so the handle structure 130 moves in-plane while a deliberate clearance gap 134 under the screw head allows smooth sliding. As the handle structure 130 slides, a first spring 135 compressed between the handle structure 130 and a protrusion structure 108 on the top plate 106 resists the motion. When the handle structure 130 reaches the end stop of the guiding slot 131, the handle has transitioned from a default latched/closed position to an unlocking position while the cable cover structure 100 remains in its closed position.

This first stage simultaneously changes the state of the releasable latch interface (e.g., guiding opening(s) 137 in FIG. 9A). Followers on the cable cover structure 100 (such as the screws/rivets 146 carried by the upper surface-mount bracket 140) shift within guiding opening(s) 137 of the handle structure 130 from retaining portions to release portions. In the retaining portions, the followers are captured so the cable cover structure 100 cannot lift. In the release portions, vertical lift is permitted.

The second stage, indicated by the curved arrow on the arrow marking 132, begins from the unlocking position. The operator may push the assembly toward the mounting surface so that the cable cover structure 100 pivots about the rotating shaft structure 110 (via insertion pin 120) from the closed position to the open position. During this rotation, the handle structure 130 moves with the cable cover structure 100 (this is the handle's open position) because the followers are in the release portions of the guiding opening(s) 137 and no longer restrain upward movement. In some embodiments a second spring 145 on a spring post 144 of the lower surface-mount bracket 150 provides an initial pop-up force that assists the start of the opening motion.

For positional clarity in the description, it is defined that the handle structure 130 has three positions and the cable cover structure 100 has two positions. The handle positions are: (i) the default latched/closed position, where the first spring 135 is relaxed, the screw 133 is at the end of the guiding slot 131 nearest the protrusion structure 108, and the followers are seated in the retaining portions of the guiding opening(s) 137 to prevent lift; (ii) the unlocking position, reached by sliding the handle structure 130 forward against the first spring 135 until the screw 133 reaches the opposite end of the guiding slot 131, where the followers are aligned with the release portions of the guiding opening(s) 137 so lift is permitted while the cable cover structure 100 is still closed; and (iii) the open position, in which the handle structure 130 accompanies the cable cover structure 100 as it pivots to the open position about the rotating shaft structure 110. The cable cover structure 100 itself has two positions (closed and open) and transitions between them only after the handle structure 130 has been moved from the default latched/closed position to the unlocking position. When the cable cover structure 100 is returned toward the closed position, the first spring 135 drives the handle structure 130 back toward the default latched/closed position so that the followers re-enter the retaining portions of the guiding opening(s) 137, thereby re-engaging the latch and securing the cable(s) without tools.

FIG. 9A illustrates operation to move the handle structure 130 from a default latched/closed position to the first position, i.e., an unlocking position, by sliding the handle structure 130 toward the protrusion structure 108 to compress the first spring 135, in accordance with some embodiments.

As the operator pushes in the direction indicated on the arrow marking 132, the handle structure 130 may translate along the guiding slot 131 while the screw 133 rides within the slot and is retained by a nut 138, with a clearance gap 134 permitting low-friction motion. During this translation the releasable latch interface may transition from a retaining state to a release state. In the retaining state, one or more followers (such as screws/rivets 146 on the upper surface-mount bracket 140, or, in some embodiments, screw heads mounted to the cable cover structure 100 or screws/rivets 146 carried by the upper surface-mount bracket 140) may be captured in guiding opening(s) 137 formed in the handle structure 130. Each guiding opening 137 may be keyhole-shaped or otherwise stepped, with a narrow retaining portion sized to closely receive the follower and resist upward lift, and a larger release portion sized to admit the follower with clearance so that upward lift is permitted. The narrow portion of each guiding opening 137 may be positioned closer to the protrusion structure 108 than the release portion so that sliding the handle structure 130 toward the protrusion structure 108 moves the follower from the retaining portion into the release portion. In the state reached at the end of this slide (i.e., the unlocking position), the cable cover structure 100 may remain in its closed position, but the followers may now reside in the release portions of the guiding openings 137 so that subsequent opening is permitted. Two guiding openings 137 may be used and arranged symmetrically to resist yaw; however, a single opening may be used, or more than two openings may be provided for added stability. Edges of the guiding openings 137 may be chamfered or radiused to case the transition, and shallow detents may be provided to give tactile feedback at the default latched position and the unlocking position. In alternative embodiments the roles may be reversed, with the guiding openings formed in the cable cover structure 100 or on the upper surface-mount bracket 140 and the followers carried by the handle structure 130; the same positional logic may apply.

FIG. 9B illustrates operation to move the handle structure 130 from the first position, i.e., an unlocking position, to the second position, i.e., an open position, by turning the handle structure 130 toward the mounting surface, in accordance with some embodiments. Because the followers now occupy the release portions of the guiding opening(s) 137, the cable cover structure 100 may pivot about the rotating shaft structure 110 (via insertion pin 120) from the closed position to the open position, and the handle structure 130 may accompany that motion with the cover. In some embodiments a second spring 145 seated on a spring post 144 of the lower surface-mount bracket 150 may apply an initial pop-up force that begins separation of the cable cover structure 100 from the lower bracket, after which continued rotation may be accomplished manually. Other opening-assist arrangements may be used, such as a torsion spring about the pivot axis, a leaf spring acting on the bottom plate 107, or an elastomeric element positioned to exert an outward bias. When the cable cover structure 100 is later returned toward the closed position, the first spring 135 may drive the handle structure 130 back along the guiding slot 131 toward the default latched/closed position so that the followers re-enter the narrow retaining portions of the guiding openings 137, thereby re-engaging the latch and securing the cable(s) without tools.

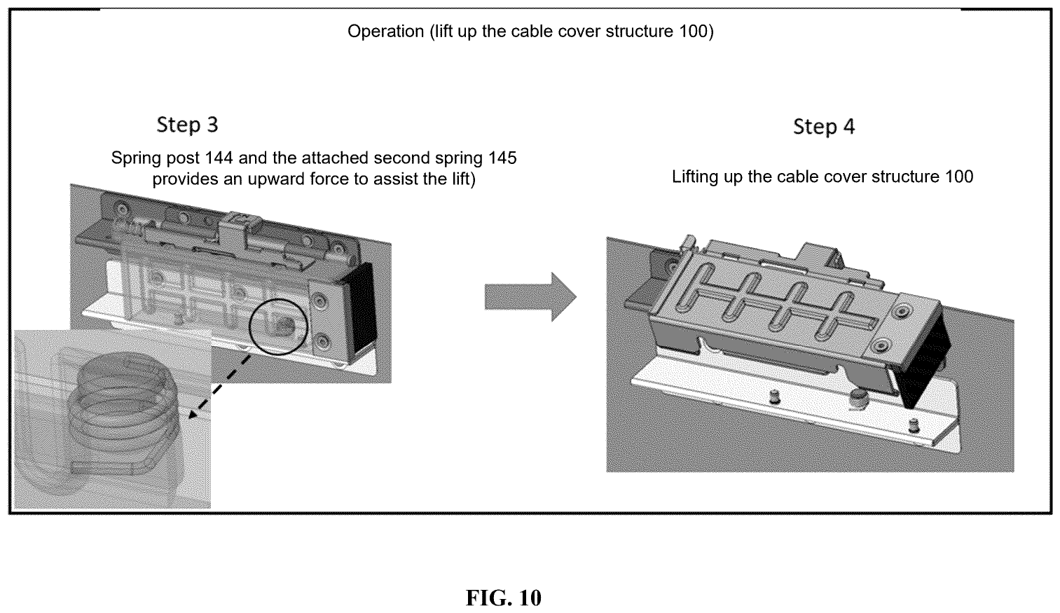

FIG. 10 illustrates a secondary spring element integrated with the lower surface-mount bracket providing an initial pop-up force to assist opening, in accordance with some embodiments.

As shown at left, a second spring 145 may be seated on a spring post 144 disposed on the outward tab of the lower surface-mount bracket 150. When the handle structure 130 has been moved from the default latched/closed position to the unlocking position (FIGS. 8-9B), the followers may occupy the release portions of the guiding opening(s) 137 so that the cable cover structure 100 may begin to lift. At this moment, the second spring 145 may exert an upward/outward bias against the underside of the cable cover structure 100 (e.g., against the bottom plate 107 or an adjacent contact surface) producing an initial separation or “pop-up” that reduces the force required by the operator to start rotation about the rotating shaft structure 110. The right-hand view illustrates the subsequent lifting motion (Step 4), during which the handle structure 130 may move with the cable cover structure 100 to the open position. In some implementations a stopper protrusion 143 on the lower surface-mount bracket 150 may also limit inward travel of cable cover structure 100 when the cable cover structure 100 returns to the closed position, thereby preserving the desired preload of the second spring 145.

The second spring 145 may be a compression coil spring as depicted, but other spring forms may be used, including a torsion spring arranged about the pivot axis near the insertion pin 120, a leaf spring acting on the bottom plate 107, an elastomeric biasing element, or a spring located on the upper surface-mount bracket 140 with an equivalent contact geometry. The spring rate and installed height may be selected to provide only a modest assist sufficient to initiate opening while avoiding excessive ejection force, and the contact interface may include a low-friction pad or cap to reduce wear during repeated cycling.

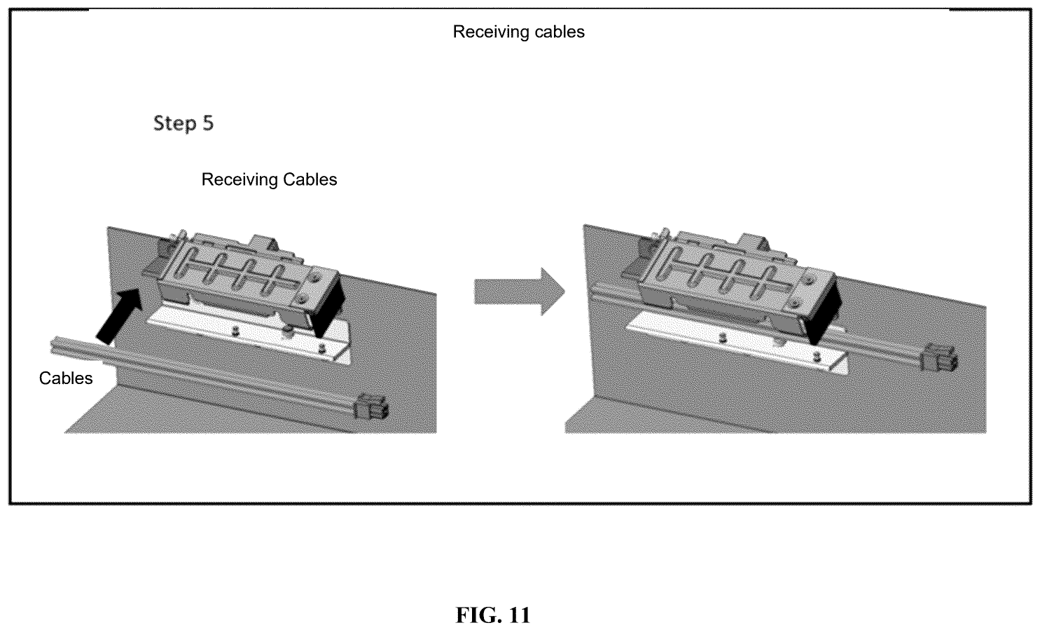

FIG. 11 illustrates an example placement of one or more cables within the interior of the cable cover structure 100 in the open position, in accordance with some embodiments. With the handle structure 130 previously moved to the unlocking position (FIGS. 8-9B), the cable cover structure 100 may be pivoted about the rotating shaft structure 110 (via insertion pin 120) so that an access window is created between the outward tabs of the upper surface-mount bracket 140 and the lower surface-mount bracket 150 and the interior face of the panel body 102. Cables may be introduced laterally from the end carrying the brush structure 150 or from the opposite end, and then laid onto the lower support defined by the lower surface-mount bracket 150 and the bottom plate 107. The reinforcement ribs of the panel body 102 may include interior guide ribs on the interior face of the panel body 102, which may serve as passive guides to maintain spacing and alignment of the cables, while side flanges and the bottom lip/retention edge may cooperate to resist cable escape when the cover is later closed.

At the brush end, the bristles 154 may elastically deflect to admit the cables through the pass-through while substantially impeding bulk airflow into the interior of the cable cover structure 100. The brush mounting plate 152 remains fastened to the cover so that the brush structure 150 moves with the cover during opening and closing. After the desired cable bundle is positioned, the cable cover structure 100 may be rotated back toward the closed position; as it approaches closure, the first spring 135 may return the handle structure 130 toward the default latched/closed position so that followers (e.g., screws/rivets 146) re-enter the retaining portions of the guiding opening(s) 137 to secure the cables without tools. In other embodiments, cables may be fed from either direction, different brush densities may be used to suit cable diameters, and the interior guides formed by the reinforcement ribs may be varied to create dedicated channels for specific cable types.

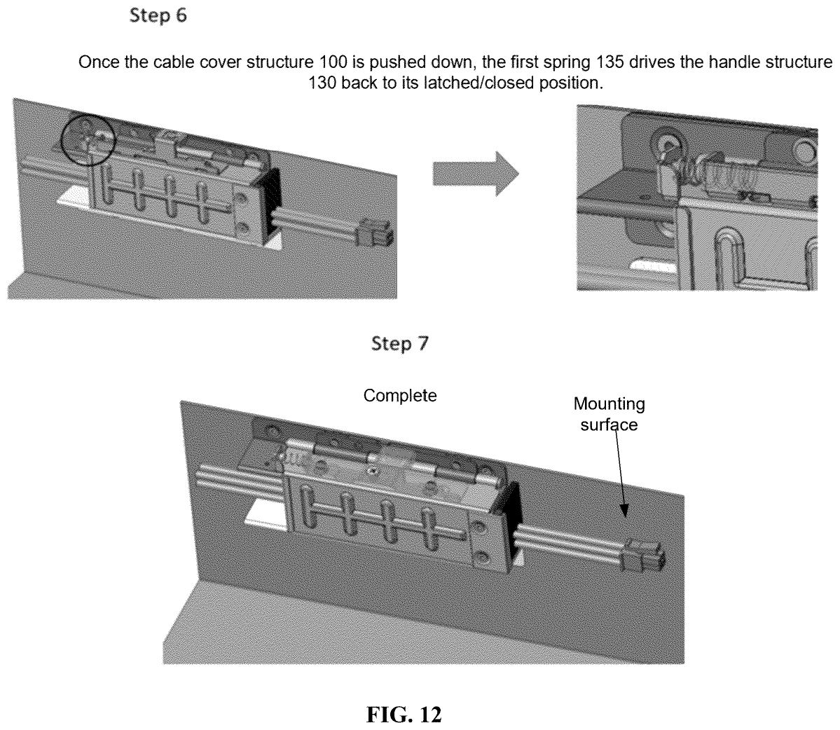

FIG. 12 illustrates closure of the cable cover structure 100 and automatic return of the handle structure 130 to the default latched position under the bias of the first spring 135, in accordance with some embodiments. In Step 6, the operator pushes the cable cover structure 100 downward so it pivots about the rotating shaft structure 110 toward the closed position. As the cover approaches the brackets, a first spring 135 disposed between a protrusion structure 108 on the top plate 106 and an end of the handle structure 130 expands and drives the handle structure 130 rearward along the guiding slot 131. This motion returns the screw 133 to the slot end nearest the protrusion structure 108 and restores the handle to the default latched/closed position. Concurrently, followers that cooperate with the releasable latch interface (e.g., rivets or studs on the cable cover structure 100 or, in some embodiments, screws/rivets 146 carried by the upper surface-mount bracket 140) move from the release portions of the guiding opening(s) 137 into their narrow retaining portions, thereby inhibiting upward lift and re-engaging the latch without tools. A stopper protrusion 143 on the lower surface-mount bracket 150 may limit inward travel for repeatable seating; any second spring 145 on a spring post 144 (used for opening assist) returns to its installed height as the cover closes.

Step 7 shows the completed, locked state: the top plate 106 overlaps the upper surface-mount bracket 140 and the bottom plate 107 overlaps the lower surface-mount bracket 150, the cable bundle is confined within the interior of the cable cover structure 100, and the handle structure 130 has fully re-latched under the bias of the first spring 135. Subsequent access may again be obtained by sliding the handle structure 130 to the unlocking position (FIGS. 8-9B), after which the cover may be lifted to the open position.

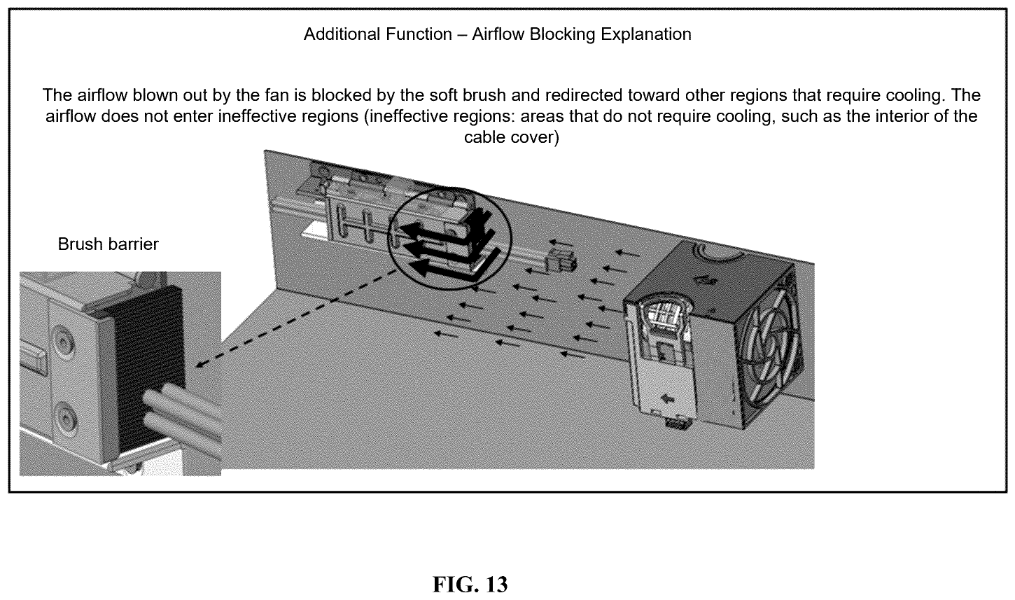

FIG. 13 illustrates the cable cover structure 100 with brush structure 150 blocking fan airflow from entering the interior of the cable cover and redirecting the airflow toward regions requiring cooling, in accordance with some embodiments. A system fan may discharge airflow along the chassis sidewall. The brush structure 150, which is carried by an L-shaped brush mounting plate 152 secured to the end of the cable cover structure 100, presents a field of flexible bristles 154 that may form a compliant barrier at the cable pass-through. The bristles 154 may deflect locally to admit one or more cables while substantially blocking bulk airflow from entering the interior of the cable cover structure 100, which is an ineffective cooling region. By impeding flow into this interior cavity, the brush structure 150 may redirect the fan airflow toward adjacent regions that require cooling, such as heat-generating components on the chassis sidewall.

Because the brush structure 150 is fixed to the cable cover structure 100, it may move with the cover during opening and closing while maintaining the airflow barrier at the end opening. The bristle density, height, and stiffness may be selected to balance sealing effectiveness with cable accommodation and may vary across the brush width to suit different cable diameters. In some embodiments the brush mounting plate 152 may be fastened by screws/rivets 146 for serviceability, and alternative edge seals (such as foam or elastomeric lips) may be used in place of, or in addition to, the bristles 154 to achieve similar airflow-blocking performance.

The various features and processes described above may be used independently of one another or may be combined in various ways. All possible combinations and sub-combinations are intended to fall within the scope of this disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, C, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

1. A cable management assembly configured to hold at least one cable on a mounting surface, comprising:
a surface-mount structure configured for attachment to the mounting surface;
a cable cover structure movably coupled to the surface-mount structure between a closed position, in which the cable cover structure retains the at least one cable, and an open position, in which the cable cover structure provides access for placement or removal of the at least one cable;
a handle structure mounted on the cable cover structure through a releasable latch interface for guided motion between a default latched position and an unlocking position;
a first spring operatively coupled between the handle structure and the cable cover structure and biasing the handle structure toward the default latched position
wherein the releasable latch interface being configured such that:
when the handle structure is in the default latched position, the cable cover structure is prevented from moving from the closed position to the open position,
movement of the handle structure against a bias of the first spring to the unlocking position permits the cable cover structure to move from the closed position towards the open position, and
returning the cable cover structure toward the closed position causes the first spring to drive the handle structure toward the default latched position to re-engage the releasable latch interface and secure the at least one cable.

2. The cable management assembly of claim 1, wherein the cable cover structure is pivotally coupled to the surface-mount structure by a rotating shaft structure, a hinge barrel on the cable cover structure, and an insertion pin extending through the rotating shaft structure and the hinge barrel to define a pivot axis.

3. The cable management assembly of claim 1, wherein the handle structure is constrained for guided motion by at least one guiding slot and a fastener that passes through the guiding slot while maintaining a clearance gap that permits sliding of the handle structure without binding.

4. The cable management assembly of claim 3, wherein the fastener comprises a screw and the clearance gap is set by at least one of a screw head geometry, a washer, or a shoulder portion of the screw.

5. The cable management assembly of claim 1, wherein the releasable latch interface comprises at least one aperture portion (guiding opening) of the handle structure and at least one follower on the cable cover structure, the aperture portion comprising a retaining portion that inhibits opening in the default latched position and a release portion that permits opening in the unlocking position.

6. The cable management assembly of claim 5, wherein the aperture portion (guiding opening) is keyhole-shaped and the follower comprises one of the rivets or studs, a boss, or a screw head on the cable cover structure.

7. The cable management assembly of claim 1, wherein the first spring is positioned between an end portion of the handle structure and a protrusion structure on the cable cover structure that serves as a spring stop, the first spring biasing the handle structure away from the protrusion structure in the default latched position.

8. The cable management assembly of claim 1, further comprising:
a second spring configured to apply an opening bias to the cable cover structure when the handle structure is in the unlocking position.

9. The cable management assembly of claim 8, wherein the second spring comprises at least one of a coil spring seated on a spring post of the surface-mount structure, a torsion spring adjacent the pivot axis, a leaf spring, or an elastomeric biasing element.

10. The cable management assembly of claim 1, wherein the surface-mount structure comprises an upper surface-mount bracket and a lower surface-mount bracket spaced from the upper surface-mount bracket to receive the cable cover structure therebetween.

11. The cable management assembly of claim 10, wherein each of the upper surface-mount bracket and the lower surface-mount bracket has a T-shaped geometry comprising a flat base configured for attachment to the mounting surface and a perpendicular tab that projects outward to support the cable cover structure.

12. The cable management assembly of claim 10, further comprising:
a stopper protrusion on at least one perpendicular tab of the surface-mount structure, the stopper protrusion limiting inward travel of the cable cover structure in the closed position.

13. The cable management assembly of claim 10, wherein a spacing between the upper surface-mount bracket and the lower surface-mount bracket is selectable to accommodate cable cover structures of different heights or cable capacities.

14. The cable management assembly of claim 10, wherein a top plate of the cable cover structure overlaps the upper surface-mount bracket and a bottom plate of the cable cover structure overlaps the lower surface-mount bracket in the closed position.

15. The cable management assembly of claim 1, further comprising:
a brush structure fixed to an end of the cable cover structure and arranged to impede airflow into an interior of the cable cover structure while permitting passage of at least one cable.

16. The cable management assembly of claim 15, wherein the brush structure comprises an L-shaped brush mounting plate secured to the cable cover structure and a bristle portion forming a flexible barrier that deflects cooling airflow away from an interior of the cable cover structure.

17. The cable management assembly of claim 1, wherein the handle structure comprises an arrow marking indicating a sliding direction toward the protrusion structure to transition to the unlocking position and a rotation direction toward the mounting surface to open the cable cover structure.

18. The cable management assembly of claim 3, wherein an end of the guiding slot proximate the protrusion structure defines a stop for the default latched position and an opposite end of the guiding slot defines a stop for the unlocking position, thereby defining a tool-free latch operation.

19. The cable management assembly of claim 1, wherein a panel body of the cable cover structure comprises reinforcement ribs that stabilize the cable cover structure.

20. The cable management assembly of claim 2, wherein the rotating shaft structure is fixed to the surface-mount structure by rivets and the insertion pin comprises an axial retention feature configured to prevent lateral migration under vibration.
